(19) United States
(12) Patent Application Publication
(10) Pub. No.: US 2015/0003030 A1
(43) Pub. Date: Jan. 1, 2015

(54) ELECTRONIC DEVICE CAPABLE OF REDUCING ELECTROMAGNETIC INTERFERENCE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: FU-LI GAO, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/141,441

(22) Filed: Dec. 27, 2013

(30) Foreign Application Priority Data
Jun. 27, 2013 (CN) 2013102621492

(51) Int. Cl. H03H 7/01

(52) U.S. Cl. CPC H03H 7/0138
USPC 361/803

(57) ABSTRACT

An example of an electronic device includes a mother board and a slave board. The mother board is electrically connected to the slave board via one cable. The electronic device further includes a first filter element and a second filter element. The first filter element is connected between a first end of the cable and ground. The second filter element is connected between a second end of the cable and the ground. The first filter element and the second filter element cooperatively filter electromagnetic waves generated by the cable.

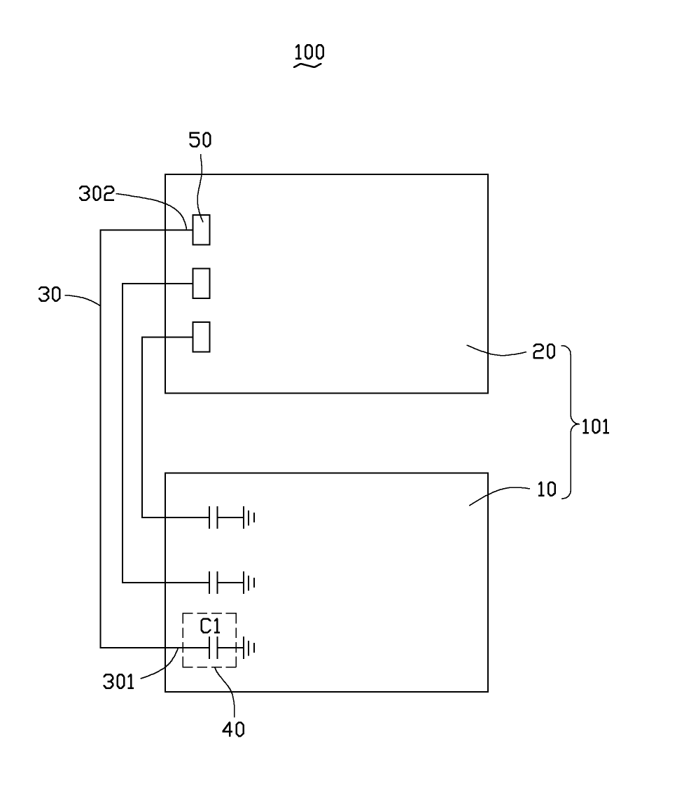

### BACKGROUND

1. Technical Field

The present disclosure relates to electronic devices, and particularly to an electronic device with a function of reducing electromagnetic interferences.

2. Description of Related Art

Cables are employed to connect different circuit boards of an electronic device. However, electromagnetic interferences are easily generated by using the cables.

Therefore, what is needed is an electronic device capable of reducing the electromagnetic interferences to solve the above-mentioned problem.

### BRIEF DESCRIPTION OF THE DRAWINGS

Many aspects of the present disclosure should be better understood with reference to the following drawing. The components in the drawing are not necessarily drawn to scale, the emphasis instead being placed upon clearly illustrating the principles of the present device.

Moreover, in the drawing, like reference numerals designate corresponding components throughout the views.

The FIGURE is a schematic view of an electronic device capable of reducing electromagnetic interference, in accordance with an exemplary embodiment.

### DETAILED DESCRIPTION

Embodiments of the present disclosure are described with reference to the accompanying drawing.

The FIGURE shows an exemplary embodiment of an electronic device 100. The electronic device 100 includes a variety of print circuit boards 101. The print circuit boards

(PCB) 101 include at least one motherboard 10 and at least one slave board 20. In this illustrated embodiment, the PCBs 101 include one motherboard 10 and one slave board 20 as an example. In this illustrated embodiment, the electronic device 100 further includes a cable 30 to connect the motherboard 10 and the slave board 20, a first filter element 40 arranged on the motherboard 10, and a second filter element 50 arranged on the slave board 20.

The cable 30 includes a first end 301 and a second end 302. The first end 301 is electrically connected to the motherboard 10, and the second end 302 is electrically connected to the slave board 20. The first filter element 40 is arranged on the motherboard 10 and is connected between the first end 301 and ground. The second filter element 50 is arranged on the slave board 20 and is connected between the second end 302 and ground.

In this embodiment, the first filter element 40 is a filter capacitor C1. One end of the filter capacitor C1 is connected to the first end 301 of the cable 30, and the other end of the filter capacitor C1 is grounded. In a second embodiment, the first filter element 40 is an EMC filter (Electro Magnetic Compatibility filter) connected between the first end 302 of the cable 30 and the ground.

In this embodiment, the second filter element 50 is also an EMC filter connected between the second end 302 of the cable 30 and the ground. In the second embodiment, the second filter element 50 is a filter capacitor connected between the second end 302 and the ground.

In some embodiments, the electronic device 100 may include several cables 30, several first filter elements 40, and several second filter elements 50. The number of the first filter elements 40, the second filter elements 50, and the cables 30 are the same. In other embodiments, the number of the first filter elements 40, the second filter elements 50, and the cables 30 are different from each other.

The first filter elements 40 and the second filter elements 50 cooperatively filter the electromagnetic waves generated by the cables 30, thus, the electromagnetic interferences is reduced.

Although the present disclosure has been specifically described on the basis of exemplary embodiments thereof, the disclosure is not to be construed as being limited thereto.

Various changes or modifications may be made to the embodiments without departing from the scope and spirit of the disclosure.

What is claimed is:

1. An electronic device capable of reducing electromagnetic interference, comprising:
a first printed circuit board;
a second printed circuit board;
at least one cable connected between the first printed circuit board and the second printed circuit board;
at least one first filter element arranged on the first printed circuit board, each of the at least one first filter element being connected between a first end of one of the at least one cable and ground; and
at least one second filter element arranged on the second printed circuit board, each of the at least one second filter element being connected between a second end of the one of the at least one cable and the ground, the at least one first filter element and the at least one second filter element cooperatively filtering electromagnetic waves generated by the at least one cable.

2. The electronic device as described in claim 1, wherein each of the at least one first filter element is a filter capacitor.

3. The electronic device as described in claim 1, wherein the number of the at least one first filter is the same as the number of the at least one cable.

4. The electronic device as described in claim 1, wherein each of the at least one first filter element is an Electro Magnetic Compatibility filter.

5. The electronic device as described in claim 1, wherein each of the at least one second filter element is a filter capacitor.

6. The electronic device as described in claim 1, wherein each of the at least one second filter element is an Electro Magnetic Compatibility filter.

7. The electronic device as described in claim 1, wherein the number of the at least one second filter element is the same as the number of the at least one cable.

8. The electronic device as described in claim 1, wherein the first printed circuit board is a mother board, and the second printed circuit board is a slave board.
